(19) United States
(12) Patent Application Publication
(10) Pub. No.: US 2015/0326175 A1
(43) Pub. Date: Nov. 12, 2015

(54) SYSTEM AND METHOD OF ROOFTOP SOLAR ENERGY PRODUCTION

(71) Applicant: Sunplicity LLC, San Francisco, CA (US)

(72) Inventor: Jeffery Wayne Austin, Mooresville, NC (US)

(21) Appl. No.: 14/707,833

(22) Filed: May 8, 2015

Related U.S. Application Data
(60) Provisional application No. 61/990,597, filed on May 8, 2014.
(60) Provisional application No. 61/990,616, filed on May 8, 2014.
(60) Provisional application No. 62/002,109, filed on May 22, 2014.

(51) Int. Cl. H02S 40/22; H02S 20/23; H02S 30/10; H01L 31/048

(52) U.S. Cl. CPC H02S 40/22; H01L 31/048; H02S 20/23; H02S 30/10

(57) ABSTRACT

A system and method of producing electrical energy using an underlying reflective surface having emissive properties and one or more bifacial solar panels arranged such that a first face of the solar panel receives primarily direct sunlight and a second face of the solar panel receives primarily indirect sunlight reflected from the underlying reflective surface.

### CLAIM OF PRIORITY UNDER 35 U.S.C. §120

This application claims priority under 35 U.S.C. §120 to U.S. Provisional Patent Application No. 61/990,597, titled “Back-to-Back Solar Collection Structure and Methods,” filed May 8, 2014, and also claims priority to U.S. Provisional Patent Application No. 61/990,616, titled “Solar Photovoltaic Apparatus and Methods,” filed May 8, 2014, and also claims priority to U.S. Provisional Patent Application No. 62/002,109, titled “Reflective Applied Surface to Increase Solar Production,” filed May 22, 2014, the contents of each application are incorporated herein in their entirety.

### BACKGROUND

1. Field

The present application is directed to the field of solar energy systems and more specifically to rooftop solar energy systems and methods of optimizing energy production using rooftop solar energy systems.

2. Background

The solar industry has experienced rapid growth and advancement in technologies over recent years. Efforts to increase efficiency of traditional PV cells, both crystalline and thin film have pushed energy production levels higher. Crystalline cells are nearing the theoretical limit of their production capacity and thin film, in its various forms lacks the historical performance record to move it into the forefront of PV applications. Bifacial technology has been around since the 1970's, and has made huge inroads into the mainstream solar industry, first through building integrated applications, and now in traditional applications. The advance of bifacial use has been primarily due to the drop in cost of raw materials and production. Traditional bifacial cells require additional steps to prepare the backside of a single cell to work in conjunction with the front side. These additional steps slow down the production of cells compared to their monofacial counterparts, it also requires the use of a completely different doping agent than that used on the opposite side. The benefit of having an additional face to provide energy production has caused the number of manufacturers of bifacial cells to double in the last 3 years. As a whole, the limitations of PV cell technology include but are not limited to the following: lack of technological and manufacturing expertise; material shortages for traditional mono crystalline cells; history and reliability for the new thin film technology; production costs; and the number of manufacturers for bifacial technology that exist in the marketplace.

The traditional applications of photovoltaic collectors harness the sun's irradiation from the face of the photovoltaic module (solar panel), which is made up of solar cells. Solar panels typically have between 40 and 72 forward facing solar cells. These solar cells collect energy from the sun and that energy; DC (Direct Current) is converted to AC (Alternating Current) via an inverter that is placed inline. The field of solar collection has remained largely unchanged with the exception of increased efficiencies of cell production, introduction of other materials in the production of cells, the coatings applied to the face of cells or the glass panels that protect and encapsulate the cells, as well as efficiencies in inverter technology. The traditional application of the technology is to place the panels in rows, oriented in a portrait or landscape fashion facing the Southern sky if located in the Northern Hemisphere or facing the Northern sky if located in the Southern Hemisphere. Systems may be placed on the ground or the rooftop or attached to the face of a structure.

Solar panels can also be placed on trackers, which are racking systems which track the movement of the sun so that the front face of a solar panel also faces the sun at a right angle. The tilt is typically 0 degrees up to the degree that corresponds to the latitude of the system placement. When applied in typical application, the technology presents several issues. On rooftops, where the panels are typically placed from 0 degrees (flat) up to 15 degrees, this creates a significant amount of coverage of the roof surface making the roof repair, replacement, and maintenance virtually impossible Also the typical solar panel placement has presented challenges for the fire department in gaining access through the rooftop. In addition, it traps heat between the roof surface and the backside of the solar panel. Solar cells are tested and verified using Standard Test Condition or STC. The STC of a solar cell is 25 degrees Celsius; however, cells will be subjected to significantly higher temperatures, 50% to 100% higher, throughout most of the year, in the latitudes conducive to solar energy production. The increase in heat occurs during the time of day and time of year when the solar cells should be most productive as they are exposed to the greatest amount of sunlight. The increased temperatures, however, significantly lower the power production of the solar cells. Typical reduction in power is between 12% and 50% across the entire array. Similar issues occur on ground mounted solar arrays, albeit less pronounced as the panels are tilted at a steeper angle allowing some of the heat to escape, thus lowering the operating temperature.

Unlike the solar industry, the roofing industry has acknowledged the benefits of “cool” roofing technologies, however, the name “cool” has become a term of art and its meaning has been diluted through improper use. The CRRC (Cool Roof Rating Counsel) as well as Energy Star have developed and maintained standards to measure the various roofing materials used today and give ratings to assist the public in identifying the actual “coolness” of a roof material. The roofing materials are rated in two areas and are then assigned an SRI (Solar Reflective Index) number to quantify its “coolness” and create a standard to which others can be compared. The first area that is tested is the roofing materials ability to reflect the Sun's Irradiation. This is most commonly identified by its “glare” factor. The spectrum of light that is produced by the sun is vast, while the light in the spectrum that is visible to the human eye (Visible Light) is very small. The largest portion of the light measured in the Sun's Irradiation on a material is based on the amount of “visible” light that is reflected. Visible light accounts for less than 7% of the suns irradiation and accounts for less than 1% of the heat created through the absorption or reflectance of that light. The visible light is capable of producing additional power by the solar collectors when those collectors are exposed to that reflective spectrum of light although the exposure need not be direct. The second measure of a roofing materials “coolness” is its Emissivity or the materials ability to release the heat absorbed by the roofing materials. Heat is created by IR radiation and is the leading cause of heating of any surface, the solar collectors, and the interior of a structure. IR is not visible to the human eye, but its presence is felt via heat. IR is also the largest source of energy to a solar collector accounting for approximately 70%. The color of a roof material, or its ability to “reflect” visible light has little to no effect on the materials ability to release the heat that has been absorbed, or its Emissivity. When reflectivity and emissivity are combined, the roofing material receives an SRI rating. Products with an SRI rating below 85 do very little to enhance solar collector production, nor do they do much to reduce the power loss from excessive heat. The final spectrum of light associated with solar is the UV rays. They provide approximately 25% of solar collector power but the UV is not measured by CRRC or Energy Star for SRI purposes.

Further, the application of the solar technology to enhance its production through utilization of materials with a high SRI rating both on the ground mounted systems as well as those mounted on structures has not been addressed by the solar industry or the roofing industry.

### SUMMARY

Embodiments disclosed herein address the above stated needs by providing a system comprising a roof coating having reflective and emissive properties such that a bifacial solar array produces electrical energy from direct sun light and reflective sun light.

In an example embodiment of the present invention, a solar energy production system comprises a reflective and emissive rooftop coating having a Solar Reflective Index of at least 75 and an emissivity index of at least 75, one or more bifacial solar panels having a first active face in direct exposure to sunlight and a second active face in direct exposure to sunlight reflected from the rooftop coating. The system maintains an average temperature around the bifacial solar panels of no more than 35% of optimal rated operating temperature of the solar panel. The system maintains an average temperature around the bifacial solar panel of no more than 35 degrees Fahrenheit of ambient conditions. The system produces up to 75% more electricity than a system using a single face solar panel.

In another example embodiment of the present invention a reflective roof coating system to increase performance of solar arrays comprises: a substrate positioned on a structure, the substrate and structure supporting a solar array, and the substrate having an outer surface; and one or more reflective top coat layers applied to at least a portion of the substrate outer surface; the top layer further comprising an acrylic, oil, alkyd or silicone polymer, and infused with a reflective coating, which may include a metal oxide; wherein the one or more reflective top coat layers have a Solar Reflective Index of at least 75 and an emissivity index of at least 75. Example embodiments of the present invention may further comprise: a base coat applied to the outer surface of the substrate, the base coat comprising acrylic, oil, acrylic or silicone polymer; and an intermediate layer comprising a sheet of non-woven material applied over the base coat and under the one or more reflective top coats.

Still further example implementations of the present invention may comprise one or more of the following features in any combination. The non-woven material comprises nylon or polyester. The reflective metal oxide comprises silicon oxide, silver oxide, aluminum oxide, titanium oxide, magnesium oxide, gold, or mixed metal oxides. The top coat layer is water impermeable. The top coat layer reflects UV, visible light, and IR radiation away from the surface of the substrate and toward the solar array. The top coat layer is applied to at least a portion of a support structure associated with the solar array. At least one top coat layer covers substantially all of the substrate to provide a water impermeable layer over the substrate and a reflective quality the substrate that reflects UV, visible light, and IR radiation away from the substrate surface in order to maintain a substrate temperature within 15 degrees Fahrenheit of ambient conditions.

In yet another example embodiment of the present invention, a method of maintaining rooftop conditions for enhanced performance of solar arrays, comprises: applying at least one or more top coat layers to a substrate of a structure supporting a solar array, wherein the one or more top coat layers comprise an acrylic, oil, alkyd or silicone polymer, and a reflective metal oxide; reflecting UV, visible light, and IR radiation away from the substrate and in the general direction of the solar array supported by the structure; and maintaining substrate temperatures within 15 degrees Fahrenheit of ambient conditions.

Example embodiments of the present invention may include one or more of the following features in any combination. The one or more reflective top coat layers have a Solar Reflective Index of at least 75 (e.g., at least 80, 85, 90, 95 or more) and an emissivity index of at least 75 (e.g., at least 80, 85, 90, 95 or more). The method further comprises: applying a base layer to an outer surface of the substrate, the base layer comprising an acrylic, oil, alkyd or silicone polymer; and applying one or more top coat layers to the base layer. The method further comprises: applying a base layer to an outer surface of the substrate, the base layer comprising an acrylic, oil, alkyd or silicone polymer; applying an intermediate layer to the base layer, the intermediate layer comprising a non-woven material that comprises nylon or polyester; and applying one or more top coat layers to the base layer. The solar array includes at least one bifacial solar panel.

And in still another example embodiment of the present invention, a method of managing operating temperature of a rooftop solar array comprises: applying one or more reflective top coat layers to a rooftop substrate supporting a solar array, the one or more top coat layers forming a reflective surface and comprising an acrylic, oil, alkyd or silicone polymer, and a reflective metal oxide; wherein the one or more reflective top coat layers have a Solar Reflective Index of at least 75 and an emissivity index of at least 75; maintaining the ambient temperature about the rooftop solar array within 25 degrees Fahrenheit of optimal performance temperatures for the solar voltaic cells within the solar array, in part by preventing heating of the substrate due to the reflectivity and emissivity of the one or more top coat layers. The method may also comprise: reflecting UV, visible light and IR radiation from the substrate and in the general direction of the rooftop array; and producing electrical energy via one or more photo voltaic cells within the solar array, wherein the photo voltaic cells are energized from radiation reflected from the one or more top coat layers on the substrate. The method may further comprise, producing electrical energy via bifacial solar panels within the solar array wherein the bifacial solar panel comprises a first face of photo voltaic cells generally aligned in the direction of the sun and opposite the substrate, and a second face of photo voltaic cells generally aligned in the direction of radiation reflected from the surface of the substrate and opposite the direction of the sun.

Example embodiments of the present invention may also include one or more of the following features in any combination. One or more photo voltaic cells within the solar array are generally aligned opposite the direction of the sun.

A further still example embodiment of the present invention includes a bifacial solar panel comprising: a first panel comprising (1) a transparent rigid front outer layer, and (2) two or more front facing photo voltaic cells, arranged in strings, and encapsulated into a polymer to form a front facing panel of photo voltaic cells aligned in the same direction; and a second panel comprising, (1) a transparent rigid back outer layer, and (2) two or more back facing photo voltaic cells, arranged in strings, and encapsulated into a polymer to form a back facing panel of photo voltaic cells aligned in the same direction; wherein the front and back panels are arranged in a back to back configuration. The transparent rigid front and back layers comprise glass, and the panels of photo voltaic cells comprise monocrystalline Si, polycrystalline Si, multicrystalline Si, amorphorus Si, nonocrystallne thin film Si, polycrystalline thin film Si, CIGS thin film, CdTe thin film, TiO2 thin film or a compounds of single or multi-junction cells. The copolymer encapsulating the photo voltaic cells comprises Ethylene-vinyl acetate. An insulating material is between the front facing panel of photo voltaic cells and the back facing panel of photo voltaic cells. The insulating material is a rigid material providing support and structure to the bifacial solar panel the front and rear facing panels of photo voltaic cells each contain between 20 and 120 photo voltaic cells arranged in strings. A double junction box is connected to the front and rear facing panels of photo voltaic cells. The front facing panel of photovoltaic cells produce electrical energy primarily from direct exposure to sunlight and the rear facing panel of photo voltaic cells produce electricity primarily from reflective or indirect sunlight. The panel is mounted on frame such that the front panel can be position at an angle of 0 degrees to 90 degrees from the horizontal plane. The bifacial solar panel is part of an array of rooftop solar panels positioned on a reflective surface.

In another example embodiment of the present invention a method of producing electricity from two differently aligned solar panels, comprises: coating a substrate with a reflective surface, the substrate being part of a rooftop; providing a bifacial solar panel comprising, (1) a first panel having a transparent rigid front outer layer and two or more front facing photo voltaic cells, arranged in strings, and encapsulated into a copolymer to form a front facing panel of photo voltaic cells aligned in the same direction, and (2) a second panel having a transparent rigid back outer layer and two or more back facing photo voltaic cells, arranged in strings, and encapsulated into a copolymer to form a back facing panel of photo voltaic cells aligned in the same direction; and then producing electricity by exposing the first panel primarily to direct sunlight and exposing the second panel to primarily reflective or indirect sunlight. The method may further comprise: providing a first bifacial solar panel aligned to capture direct sunlight on a first panel during a first part of the day; and providing a second bifacial solar pane aligned to capture direct sunlight on a first panel during a second part of the day; wherein the second panels of the first and second bifacial solar panels capture reflective or indirect sunlight reflected from the reflective coating on the substrate during both the first and second part of the day. The method may utilize an array of bifacial solar panels. The reflective coating has a Solar Reflective Index of at least 75 and an emissivity index of at least 75. The method may also include maintaining the ambient temperature about the bifacial solar panel within 25 degrees Fahrenheit of optimal performance temperatures for the solar voltaic cells within the solar array, in part by preventing heating of the substrate due to the reflectivity and emissivity of the reflective coating.

And in yet another example of the present invention a modular framing system for supporting a bifacial solar panel comprises: one or more frame members, each comprising a channel and a gasket, wherein the framing member is configures to secure at least one edge of a bifacial solar panel; two or more risers adjustably connected to the frame member with an adjustable attachment such that the frame member can be rotated to an angel with respect to the two or more risers; and a base portion connected to the riser; wherein the modular framing system provides a minimal foot print on a mounting surface. The modular framing system may also comprise: a first and second bifacial solar panel, each bifacial solar panel including (1) a first panel having a transparent rigid front outer layer and two or more front facing photo voltaic cells, arranged in strings, and encapsulated into a copolymer to form a front facing panel of photo voltaic cells aligned in the same direction, and (2) second panel having a transparent rigid back outer layer and two or more back facing photo voltaic cells, arranged in strings, and encapsulated into a copolymer to form a back facing panel of photo voltaic cells aligned in the same direction; wherein one or more framing members support one or more edges of each of the first and second bifacial solar panels and at least one central frame member supports an edge portion of the first bifacial solar panel and an edge portion of the second bifacial solar panel; and wherein a riser is connected to the at least one central frame member.

The advantages of the present invention include, without limitation, more power production per square foot than a traditional solar system. The use of a surface coated with a highly reflective material that has an SRI of 85 or greater will generate substantially more power. Additionally, the reflective surface with an SRI of 85 or greater will be extremely efficient at reflecting the IR electrons that generate most of the heat found under traditional solar applications. The IR electrons are permitted to escape upward, cooling the surface and generating more energy in the solar collector.

The advantages of the present invention include, without limitation, generation in excess of 30% more power production per square foot than a traditional solar system. The use of a back-to-back solar collection structure and methods permit the user to maximize production of energy based on utilizing both the front and back of a module/panel utilizing similar technologies used in the current marketplace.

### BRIEF DESCRIPTION OF THE DRAWINGS

FIG. 1 is a side view of an example embodiment of solar collector positioned on top of or attached to the reflective applied surface;

FIG. 2 is a side view of an example embodiment solar collector positioned on top of or attached to the reflective applied surface of FIG. 1;

FIG. 3 is a side view of an example embodiment of solar collector positioned on top of or attached to the reflective applied surface of FIG. 1;

FIG. 4 is a side view of an example embodiment of a solar collector positioned on top of or attached to the reflective applied surface of FIG. 1;

FIG. 5 is a side view of an example embodiment of a solar collector positioned on top of or attached to the reflective applied surface of FIG. 1;

FIG. 6 is a flow chart of an example life cycle of a reflective surface of the present invention.

FIG. 7 is a flow chart of an example embodiment of a Back-to-Back Module Construction Structure;

FIG. 8 is a cut away side view of an example embodiment of a Back-to-Back Module Structure of the present invention;

FIG. 9 is a cross section of an example embodiment of a Back-to-Back Module Structure of FIG. 2;

FIG. 10 is an expanded view of an example embodiment of a Back-to-Back Module Structure of FIG. 2;

FIG. 11 is an expanded view of an example embodiment of a Back-to-Back Module Structure of the present invention;

FIG. 12 is an expanded view of an example embodiment of a Back-to-Back Module Structure of the present invention;

FIG. 13 is a front view showing placement of an example embodiment of a double junction box on a Back-to-Back Module Structure of the present invention;

FIG. 14 is a front view showing alternate placement of an example embodiment of a double junction box on a Back-to-Back Module Structure of FIG. 7.

FIG. 15 is a front view showing alternate placement of a an example embodiment of double junction box on a Back-to-Back Module Structure of FIG. 7;

FIG. 16 is a front view showing alternate placement of an example embodiment of a double junction box on a Back-to-Back Module Structure of FIG. 7;

FIG. 17 is a front and rear view showing alternate placement of an example embodiment of a double junction box on a Back-to-Back Module Structure of FIG. 7.

FIG. 18 is a front view of an example embodiment of a Solar Photovoltaic Apparatus of the present invention;

FIG. 19 is a top view of an example embodiment of a Solar Photovoltaic Apparatus of FIG. 1;

FIG. 20 is a side view of an example embodiment of a Solar Photovoltaic Apparatus of FIG. 1;

FIG. 21 is a side cross-section view of an example embodiment of a Solar Photovoltaic Apparatus of FIG. 1;

FIG. 22 is a top view of an example embodiment of a multiple Solar Photovoltaic Apparatus layout of FIG. 1;

FIG. 23 is a front cross-section view of an example embodiment of a Solar Photovoltaic Apparatus of FIG. 1;

FIG. 24 is a top cross-section view of an example embodiment of a Solar Photovoltaic Apparatus of FIG. 1.

### DETAILED DESCRIPTION

The solar industry has long known that reflectivity can increase production of solar and solar collectors have been placed on mirrors, water, sand, shells and other materials known to reflect visible light waves. Prior reflective materials have an increased incidence of reflectivity of diffused solar radiation within the ultraviolet (UV) and visible wavelengths of sunlight radiation while little is understood about the emissivity of these technologies and how heat from infrared (IR) radiation is controlled. The roofing industry has long known that roofing materials that are high in metal oxides are reflective of UV and visible wavelengths of light and some are highly emissive in that they maintain a temperature that is close to ambient thereby cooling the surface and the interior structure under the roof coating. Currently, the solar industry has not recognized these roofing materials for the purposes of waterproofing, sustainability and the use of these roofing materials that can reflect, on a continued basis for the life of the solar collector with subsequent recoats, the UV, visible and IR light waves in a manner that increases the output of the solar collector for the life of the solar collector. The solar industry has also not recognized this roofing material may be applied beneath and surrounding the solar collectors thereby cooling the area immediately around the solar collectors lowering the operating temperature during times when the operating temperatures would otherwise be in excess of the 25 degrees Celsius or 77 degrees Fahrenheit which is the stated test condition or ideal condition established by the solar industry as the normal operating temperature in the standard test condition (STC). Additionally, there is no current roofing material that is being used to generate more energy from a solar collector by using a roof system which contains a highly reflective coating that is also highly emissive allowing the solar collector to operate closer to an ambient temperature or closer to the normal operating temperature stated in the STC. Moreover, most rooftop solar panels are have a single operating face and do not take advantage of reflective light from the rooftop.

Example embodiments of the present invention include a rooftop coating system having reflective and emissive properties to direct reflective light toward a rooftop solar array while at the same time preventing overheating of the roof and conditions around the solar array, which would diminish the efficiency of the photvoltaic cell in the panel. The reflective and emissive rooftop coating is used in conjunction with a system of bifacial solar panels having a first panel aligned for direct exposure from sunlight and a second panel aligned for exposure to reflective light from the rooftop coating. The bifacial solar panels are supported by a frame and support structure that present minimal obstructions and shadows, does not interfere with the panels, and is adjustable to multiple angles from a horizontal solar panel to a vertical solar panel.

Rooftop Reflective and Emissive Coating

Example embodiments of the present invention include a reflective applied surface or reflective top coat having relatively high emissivity index. On top of or attached to the reflective applied surface is a solar collector. The sun's solar irradiation in full spectrum is reflected by the reflective applied surface and is collected by the solar collector. In some embodiments the reflected light energy is collected on a panel substantially aligned with the reflective applied surface. For example, the solar panel is aligned such that a plane faces the reflective surface between a 0 degree angle (horizontal) and a 90 degree angle (vertical).

The sun's solar irradiation in the IR range is absorbed as heat by the reflective applied surface and then emitted at approximately the same rate as it is absorbed by the reflective applied surface. In some example embodiments heat is emitted at a rate of 50% or more to as much as approximately the same rate as the rate heat is absorbed by the reflective surface. A nominal amount of the sun's solar irradiation in the IR range is collected by the solar collector with remainder of heat rising away from the reflective applied surface and the solar collector.

In example embodiments of the invention, the solar collector positioned on top of or attached to, and surrounded by the reflective applied surface is fixed in a position of various degrees of orientation from horizontal to vertical. The sun's solar irradiation in full spectrum is reflected by the reflective applied surface and is collected by solar collector.

In various example embodiments the reflective applied surface may or may not have a non-woven fabric embedded in a polymer base coat. If present, the non-woven fabric may be made of a material such as nylon or polyester. The base coat, if present, may be made of various materials such as an acrylic, oil, alkyd, or silicone polymer. On top of the polymer base coat with non-woven fabric, if present, or on top of the solid substrate if not present, is applied a minimum of two separate coats of a reflective top coat. The reflective top coat is made of a material such as acrylic, oil, alkyd, or silicone polymer and infused with reflective metal oxides or mixed metal oxides. The metal oxides may comprise Further, the reflective applied surface is a sufficiently sustainable surface which reflects and emits the suns light and heat, specifically UV, visible, and IR light ways, with a sufficiently high SRI (Solar Reflective Index) such as about 70 or above (e.g, about 75 or above, about 85 or above, about 95 or above). Further, the solar collector may be made of various materials provided by a variety of manufacturers in the current marketplace.

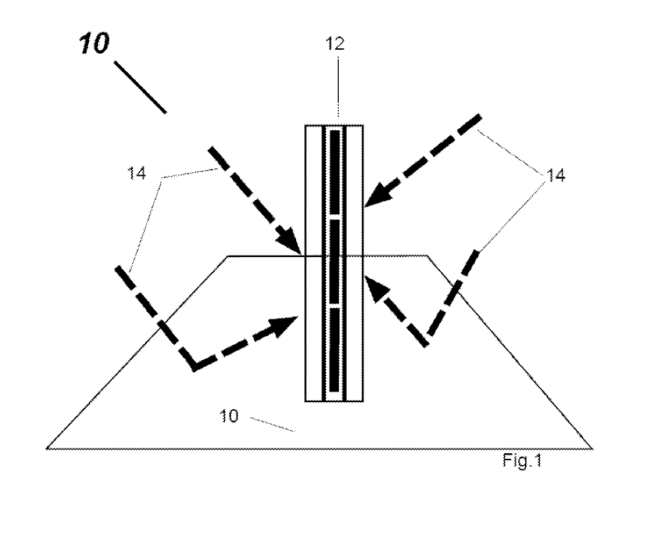

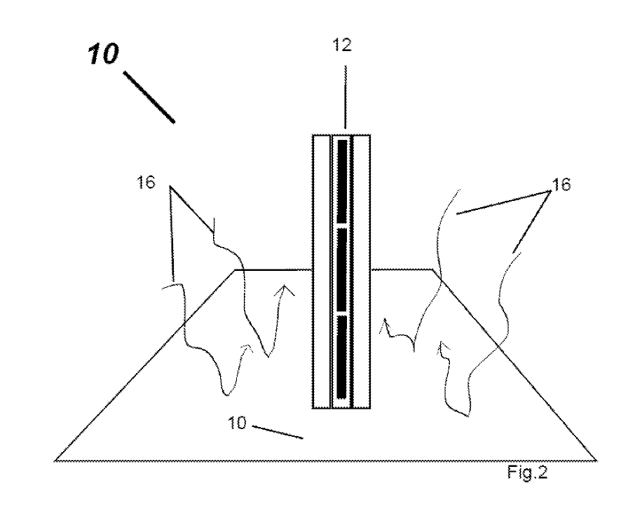

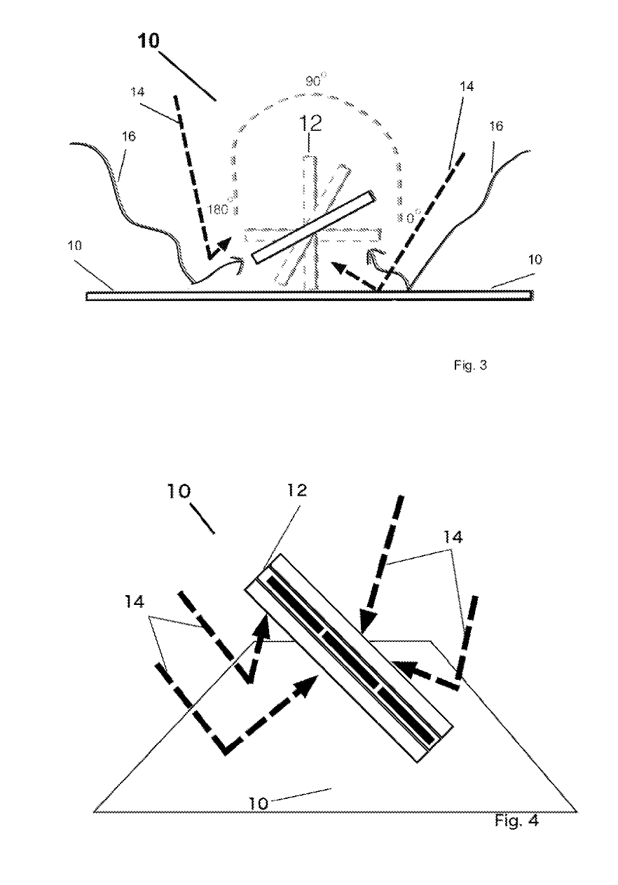

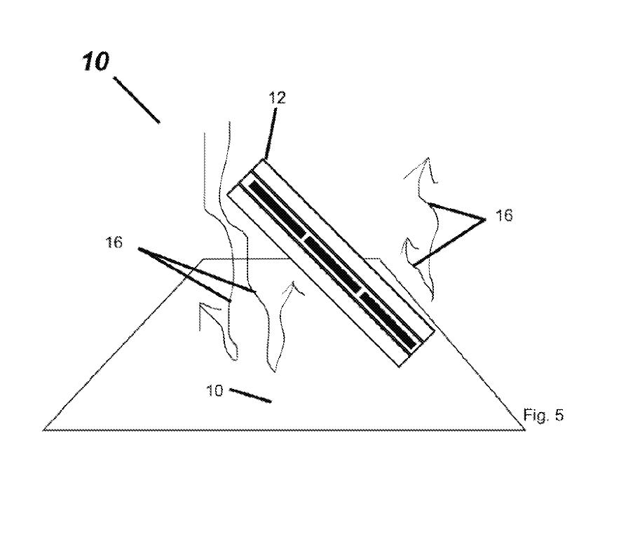

FIGS. 1 through 5 illustrate an example embodiment of a reflective applied surface 10 or a reflective rooftop coating. As illustrated attached to or positioned above the reflective applied surface 10 is solar collector 12. There is also shown the sun's solar irradiation in full spectrum 14 and the sun's solar irradiation in the IR range 16. The sun's solar irradiation in full spectrum 14 is reflected by the reflective applied surface 10 and is collected by solar collector 12. The sun's solar irradiation in the IR range 16 is absorbed as heat by the reflective applied surface 10 and then emitted at approximately the same rate as it is absorbed by the reflective applied surface 10. A nominal amount is collected by solar collector 12 with remainder of heat rising away from the reflective applied surface 10 and the solar collector 12.

The solar collector 12 positioned on top of or attached to, and surrounded by the reflective applied surface 10 is movably fixed in a position of various degrees of orientation from horizontal to vertical, the sun's solar irradiation in full spectrum 14 is reflected by the reflective applied surface 10 and is collected by solar collector 12.

The solar collector 12 positioned on top of or attached to, and surrounded by the reflective applied surface 10 is fixed in a position of various degrees of orientation from horizontal to vertical, the sun's solar irradiation in the IR range 16 is absorbed as heat and then emitted at approximately the same rate as it is absorbed by the reflective applied surface 10. A nominal amount is collected by solar collector 12 with remainder of heat rising away from the reflective applied surface 10 and the solar collector 12.

Further, solar collector 12 may be made of various materials provided by a variety of manufacturers in the current marketplace.

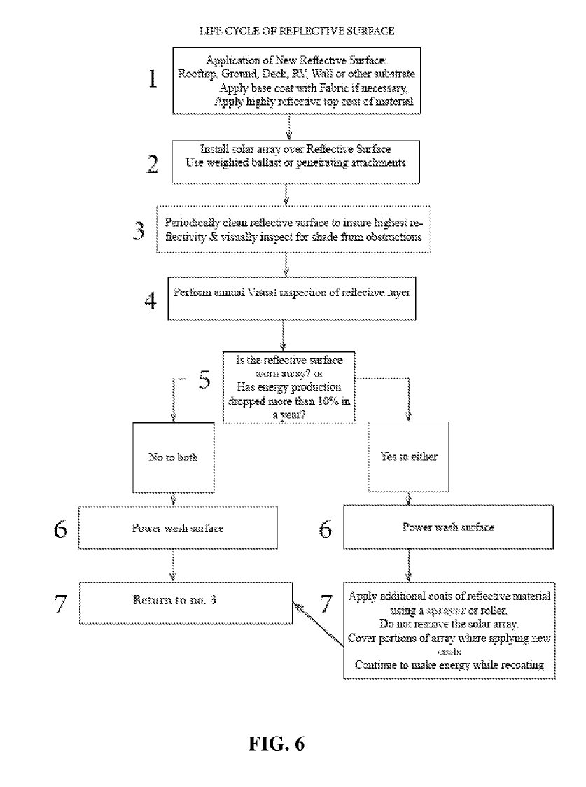

FIG. 6 shows a flowchart illustrating the life cycle of an example embodiment of a reflective surface of the present invention. As shown, the reflective surface is applied to a substrate (1). The reflective surface can be installed with or without the non-woven fabric or the base layer. One or more reflective top coats are applied to the substrate. In some example embodiments, the substrate is a rooftop surface, a deck, a platform, a patio, a prepared surface, a raised surface, or any other surface suitable for supporting an array of one or more solar panels and is capable of receiving the reflective coating. The solar array is then installed over the reflective surface (2). The solar panel array may be installed using any number of conventional techniques including weighted ballast or penetrating attachments. The reflective surface is periodically cleaned (3) to ensure the highest reflectivity. Additional visual inspections of the reflective surface may be performed on a regular basis (4). If the reflective surface is worn, damaged, or otherwise not in optimal operating conditions, e.g., energy production has dropped mor than approximately 10% in a measured time period, such as two seasons, two quarters, one year, etc., than the surface should be power washed (6) and an additional top reflective coat may be applied by spray nozzle or roller application.

The advantages of the present invention include, without limitation, more power production per square foot than a traditional solar system. The use of a surface coated with a highly reflective material that has an SRI of 75 or greater will generate substantially more power. Additionally, the reflective surface with an SRI of 75 or greater will be extremely efficient at reflecting the IR electrons that generate most of the heat found under traditional solar applications. The IR electrons are permitted to escape upward, cooling the surface and generating more energy in the solar collector.

Bi-Facial Solar Panel:

Additional embodiments of the present invention include T a back-to-back, a bifacial, or a two oppositely aligned panel application of solar collection structures utilizing traditional photovoltaic (PV) cell technology in order to promote the additional collection of solar radiation from forward facing and rear facing solar collectors, which occupying the same area as a traditional solar collector.

Example embodiments of the back-to-back or bifacial module structure consists of layers of glass, copolymer, front facing PV cells, rear facing PV cells, clear back sheet, and secured with or without a frame. A double junction box, with front side electrical connectors and rear side electrical connectors, is attached to the structure.

In some embodiments of the invention, the back-to-back module structure or bifacial solar panel may comprise forty to eighty of the front facing PV cells that are arranged in strings as with a traditional modular layout with the front facing PV cells all facing the same direction and encapsulated in a polymer or copolymer, with an additional forty to eighty rear facing PV cells arranged in strings, encapsulated in a polymer or copolymer, and facing the opposite direction of front facing PV cells in a back-to-back configuration.

The back-to-back module or bifacial solar panel may include the following features. The glass as indicated herein may be glass or any other sufficiently clear, rigid or strong material. Front facing PV cells and rear facing PV cells may be a layer of solar material, such as: mono crystalline Si, polycrystalline Si, multi crystalline Si, Amorphorus Si, Nanocrystalline thin film Si, Polycrystalline thin film Si, CIGS thin film, CdTe thin film, TiO2 thin film or other similar compounds single or multi junction cells. The cells are encapsulated between the layers of copolymer such as Ethylene-Vinyl Acetate (EVA). The encapsulated PV cells are layered between clear back sheets, which can be thin pieces of glass or other substrate that is clear and sufficiently strong to provide rigidity to the module/panel, and of a material that is an insulator to the two separate energy-producing fields.

FIG. 7 shows a flowchart illustrating an example embodiment of a back-to-back module construction structure and provides various methodologies of building a back-to-back solar collection structure. As illustrated, the front facing PV cells are selected (1). The front facing PV cells are organized into strings with appropriate electrical connections and the front facing PV cells are placed behind a protective clear outer surface such as, for example, glass, Plexiglas, or EVA (2). Then the rear facing PV cells are selected (3), and organized into strings behind a protective clear outer surface such as, for example, glass, Plexiglas, or EVA (4). The front side PV collector and the back side PV collector are aligned to form a back-to-back or bifacial arrangement such that PV sells face opposite directions (5). An insulating material may be placed between the front facing panel and the back facing panel (5a). The insulating material may be the same or different as the protective clear outer surface. The front facing panel, the rear facing panel, and the additional insulation layer are placed together to form a back-to-back or bifacial solar panel (6). The back-to-back or bifacial solar panel is sealed using a chemical adhesive or a liquid sealant (7). Junction boxes are applied to the panel and additional electrical connections are made (8). The back-to-back panel may be incorporated into a modular frame or used without a frame (9).

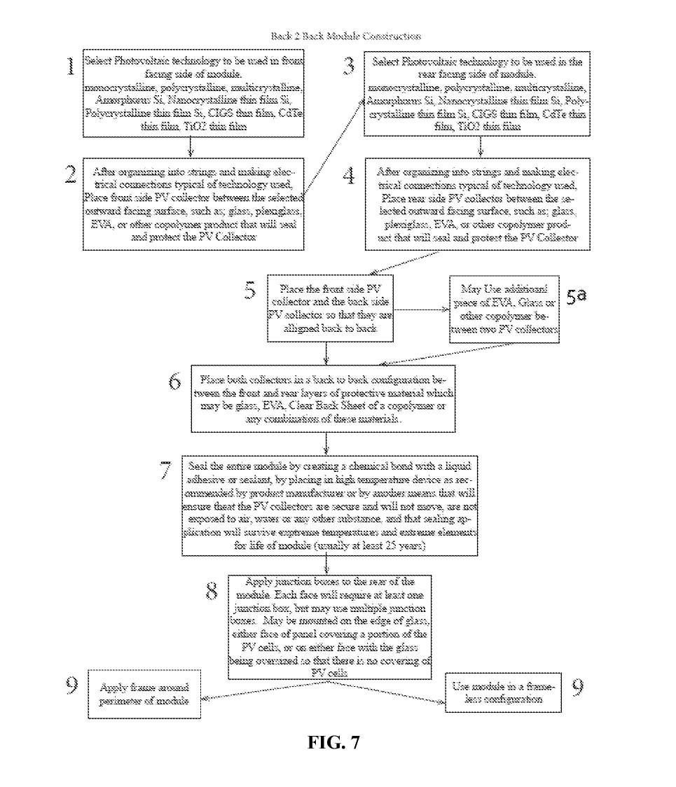

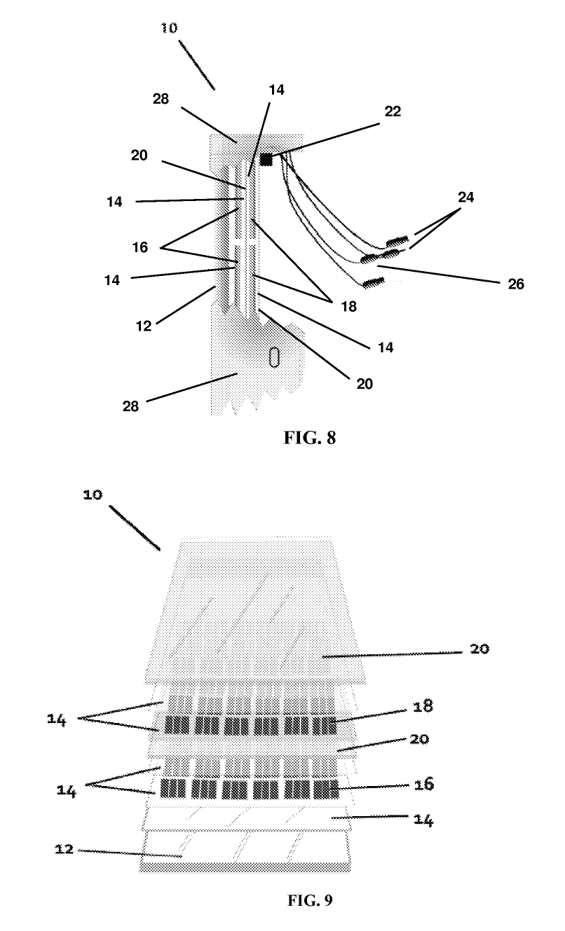

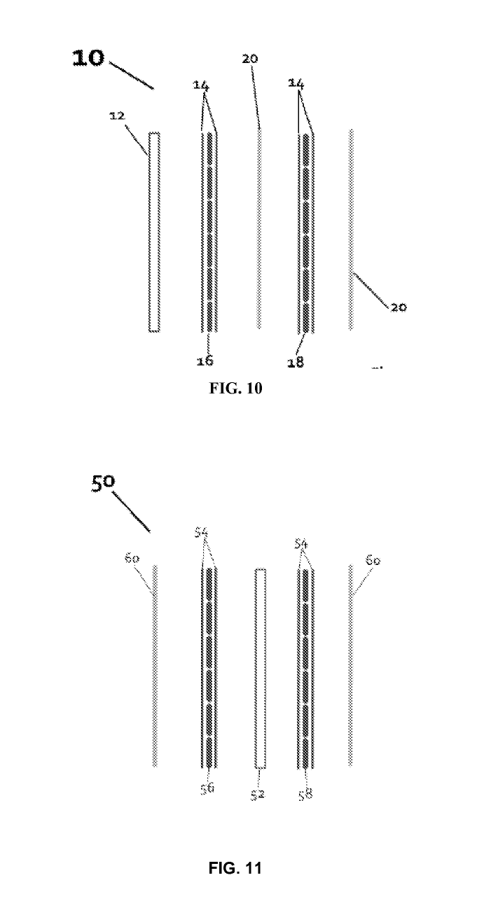

Referring now to FIGS. 8 through 10 show a back-to-back module structure or bifacial solar panel 10. The back-to-back module structure 10 comprises layers of glass 12, copolymer 14, front facing PV cells 16, rear facing PV cells 18, clear back sheet or insulation layer 20, and secured with frame 28. A double junction box 22, with front side electrical connectors 24 and rear side electrical connectors 26, is attached to the structure.

In one example embodiment of the present invention the back-to-back module structure 10 or bifacial solar panel 10 may further comprise forty to eighty of the front facing PV cells 16 arranged in strings as with a traditional modular layout with the front facing PV cells 16 all facing the same direction and encapsulated in copolymer 14, with an additional forty to eighty rear facing PV cells 18 arranged in strings, encapsulated in copolymer 14, and facing the opposite direction of front facing PV cells 16 in a back-to-back configuration. The back-to-back module structure 10 may be sufficiently wide, long and deep as with a traditional solar module/panel, such as about 20 to 50 inches in width, 40 to 90 inches in length, and 1 to 2 inches in depth. Other dimensions are contemplated and may be tailored to a specific surface to maximize exposure to direct sunlight and reflective sunlight from the underlying reflective coating.

Referring to FIG. 11, an example embodiment of a back-to-back module structure 110 is shown. The back-to-back module structure 110 comprises layers of copolymer 114, front facing PV cells 116, rear facing PV cells 118, clear back sheet 120. The back-to-back module structure 110, forty to eighty of the front facing PV cells 116 are arranged in strings as with a traditional modular layout with the front facing PV cells 116 all facing the same direction and encapsulated in copolymer 114, with an additional forty to eighty rear facing PV cells 118 arranged in strings, encapsulated in copolymer 114, and facing the opposite direction of front facing PV cells 116 in a back-to-back configuration. The back-to-back module structure 110 is sufficiently wide, long and deep as with a traditional solar module, such as about 20 to 50 inches in width, 40 to 90 inches in length, and 1 to 2 inches in depth.

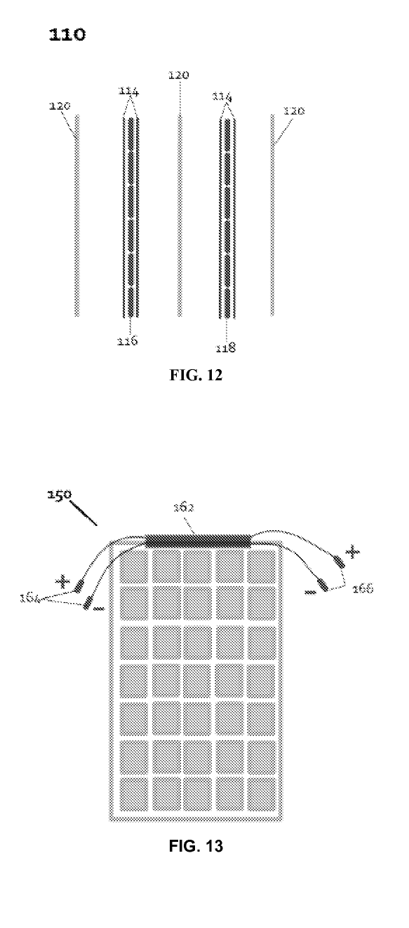

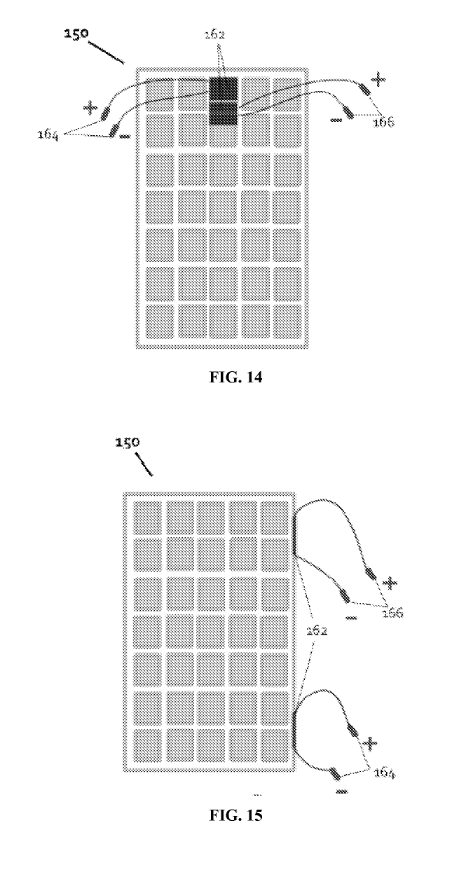

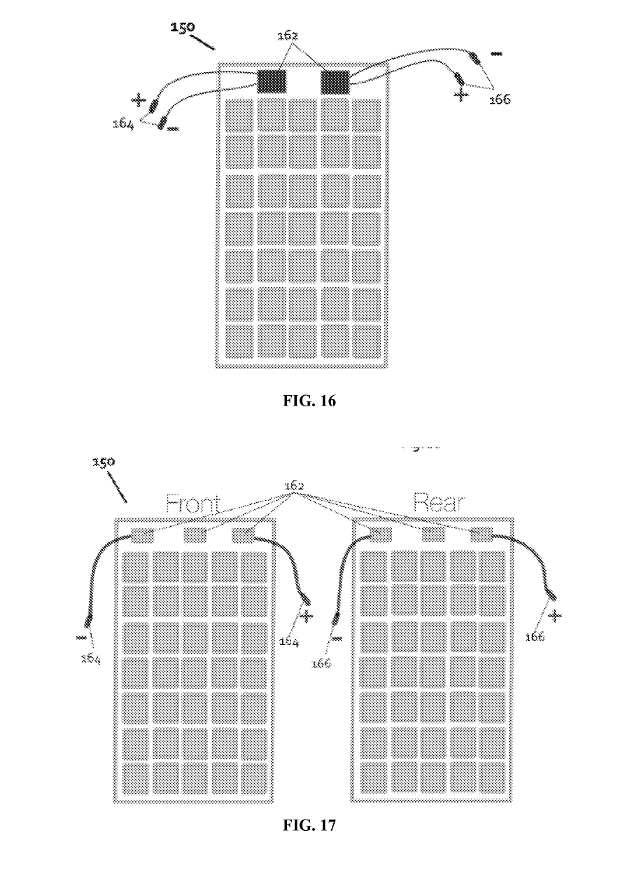

FIGS. 12 through 16 show a back-to-back module structure 150. The back-to-back module structure 150 includes a double junction box 162, with front side electrical connectors 164 and rear side electrical connectors 166. The back-to-back module structure 150, illustrates a variety of placement for the double junction box 162 with associated front side electrical connectors 164 and rear side electrical connectors 166.

The advantages of the present invention include, without limitation, generation in excess of 30% more power production per square foot than a traditional solar system. The use of a back-to-back solar collection structure and methods permit the user to maximize production of energy based on utilizing both the front and back of a module/panel utilizing similar technologies used in the current marketplace.

Apparatus for Supporting a Bifacial Solar Photovoltaic Panel:

In broad example embodiment, the present invention is a semi-vertical to vertical oriented solar photovoltaic apparatus that enhances cooling of the photovoltaic modules and the methods used to enhance generation of energy.

Example embodiments of the present invention further include a solar photovoltaic apparatus that is adjustable from 0 degrees to 90 degrees and placed on a reflective coating surface, wherein the solar photovoltaic apparatus is oriented so that two faces of the solar modules are directed in opposite directions.

In further example embodiments of the present invention the modules are placed at an angle greater than 45 degrees and up to and including 90 degrees from horizontal; or perpendicular to the ground or roof surface; the solar modules are directed with the front face or top face directed to the East and the rear face or bottom face directed to the West; or with the front face or top face directed to the West and the rear face or bottom face directed to the East. When the modules are placed at 5 degrees to 45 degrees from horizontal, the solar modules are directed with the front or top face directed to the South, and rear or bottom face directed to the North; or with the front or top face directed to the North, and rear or bottom face directed to the South. The apparatus consists of extruded vertical risers, which are joined at the bottom by a fixed or adjustable plate enabling the vertical riser to be fixed in the desired position to achieve the desired angle. Across or horizontal brace is secured at the bottom of the vertical risers with a brace plate. An additional cross brace may be used and secured at the top of the horizontal riser with the cross braces of both horizontal risers when perpendicular to the vertical risers. The vertical risers are attached to an additional horizontal foot that runs perpendicular to the horizontal brace on the horizontal plane. A horizontal foot is attached to the bottom of the vertical riser with a plate so that the horizontal foot provides lateral support for the vertical riser as well as creates a point of attachment or contact with the roof surface or the ground. The horizontal foot is secured or anchored by use of ballasting with weighted material or by mechanical attachment to the surface upon which it is sitting.

In still further example embodiments of the present invention the solar modules are attached to the racking by use of clamping devise approved by the module manufacturer which is inserted into the grooves of the upper and lower horizontal cross braces and attaching to the module or the frame of the module. Additionally, the modules that are without frames may be inserted into the channels of the extruded vertical, upper and lower horizontal cross brace where the module is surrounded on at least two of the vertical edges and the bottom horizontal edge; or the two horizontal edges of a landscape mount. The use of the top horizontal edge will be mandatory only when needed to provide additional support. A rubber gasket or other suitable material may be inserted into the channel material of the vertical and horizontal extrusions, with the edge of the solar module sitting first within the gasket and with the gasket set firmly with in the channel, thus providing a cushion for the solar module against movement, vibration, expansion and contraction. The use of the channel within the extruded vertical riser and the horizontal cross braces increase the rate of installation of the solar modules into the racking apparatus by eliminating the mechanical clamps, nuts and bolts required to physically attach the solar module to the racking apparatus. The time saved, and the reduction in use of mechanical fasteners represents a significant cost savings to the overall cost of the solar installation.

The racking apparatus of each solar module is connected to the racking apparatus of the adjacent solar modules, whereas multiple panels may be attached in a row and whereas multiple rows may be attached forming a monolithic structure. The size of the monolithic structure can range from two modules to any number supported by the underlying structure or fitting within the perimeters of the array field. The interlocking of the monolithic structure provides overall strength and rigidity to the array and reduces the amount of attachments to the roof or ground surface or ballast needed to secure the array against movement. The reduction in weight, material, and labor represent an additional savings in the overall cost of the array as well as increasing the over all stability of the solar array.

The monolithic solar array may be further strengthened by allowing the perimeter rows of solar modules to be tilted or angled at a lower degree from horizontal than the remainder of the array thus providing a wind shield that will disrupt the natural flow of wind as it impacts the solar array. The angle of the perimeter row of solar modules will be determined based on location and prevailing and historical wind conditions.

The solar photovoltaic apparatus holds the solar modules in a sufficiently semi-vertical to vertical position and is sufficiently oriented on the reflective surface coating in such a way to maximize direct, indirect, reflective and diffused lighting on both the front and rear of solar modules.

In additional example embodiments of the present invention vertical risers are sufficiently long enough to hold one to two solar modules or more, in a portrait or landscape position. The reflective coating surface may be placed under the solar photovoltaic apparatus and extend sufficiently out in all directions from edge of the solar photovoltaic apparatus.

Example embodiments of the solar photovoltaic apparatus of the present invention comprise one or more vertical risers, one or more horizontal cross braces, horizontal foot, flat and angled plates for attaching pieces, hinge or other joint, panel clamp or channel gasket, and may be made of metal or any other sufficiently rigid or strong material such as high-strength plastic or carbon fiber, and the like. The reflective coating surface is a sufficiently sustainable surface, which reflects and emits the suns light and heat, specifically ultraviolet, visible, and infrared light waves, with a sufficiently high SRI (Solar Reflective Index) such as a highly reflective material that has an SRI of 75 or greater to generate substantially more power as the vertical to semi-vertical orientation of the solar panels will permit the light to reflect off of these applied surfaces, together will generate in excess of 15% to 75% more power than single faced solar panels.

Additionally, the reflective surface with an SRI of 75 or greater will be extremely efficient at reflecting the IR electrons that generate most of the heat found under traditional solar. The IR electrons are permitted to escape upward, cooling the surface and generating more energy in the solar cells. In addition, the adjustable apparatus permits the user to maximize these benefits by providing multiple adjustment points depending on the conditions, latitude, shading, panel technology, and type of reflective surface. When the apparatus is used in conjunction with bifacial cell technology, back-to-back cell technology, or back-to-back panel technology, the amount of power produced per square foot increases exponentially.

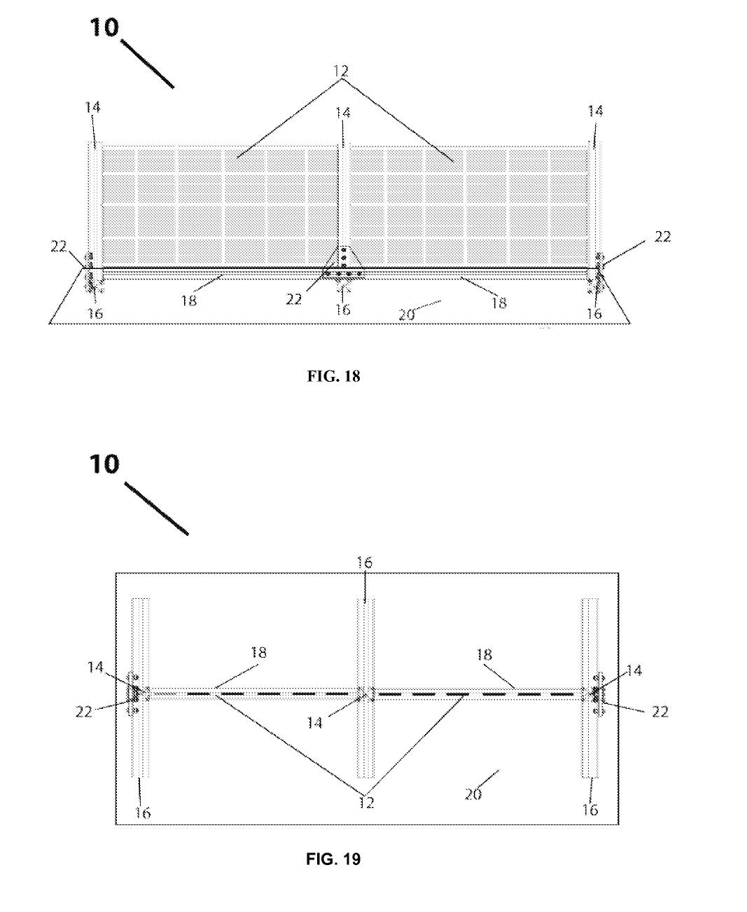

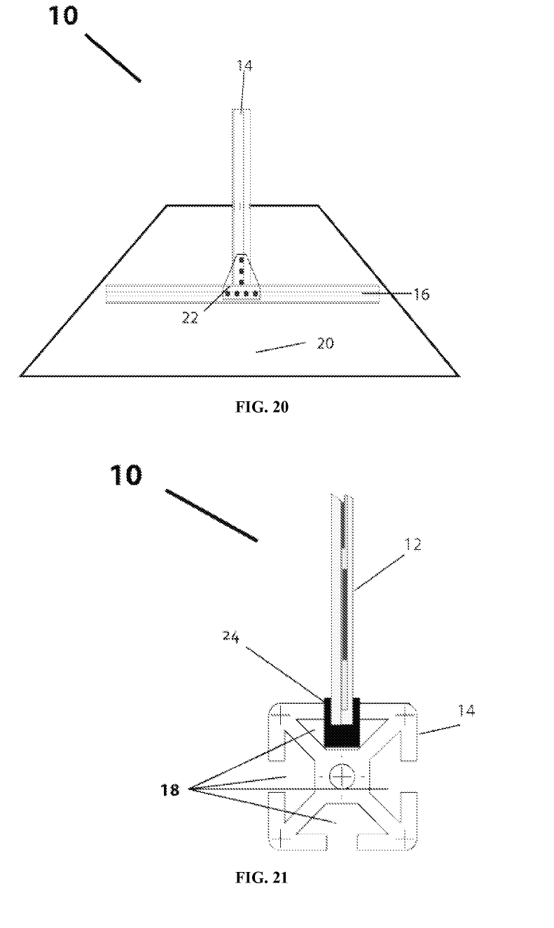

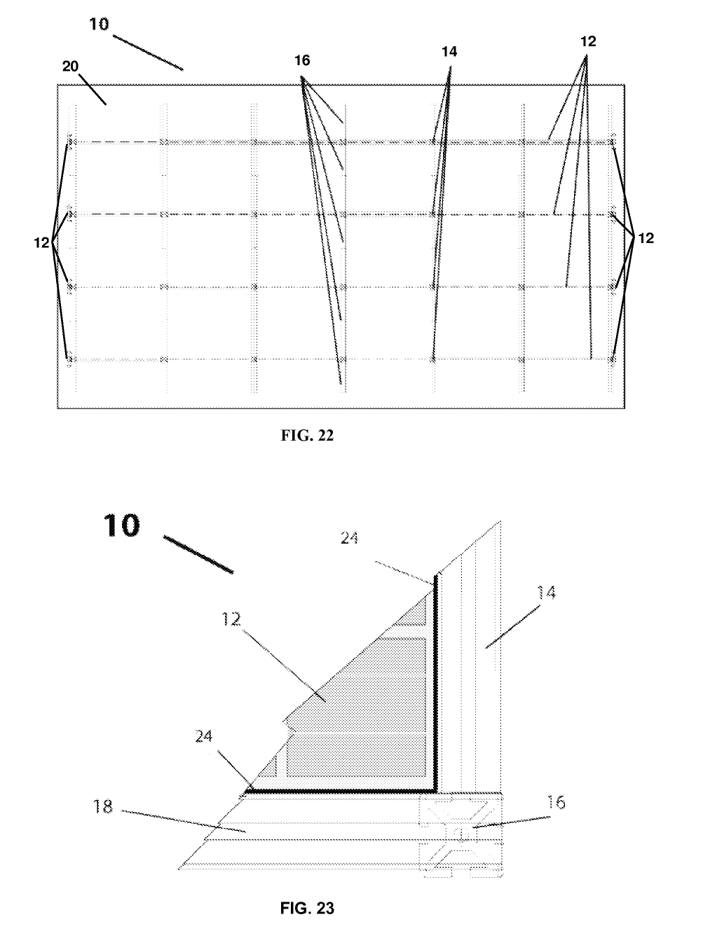

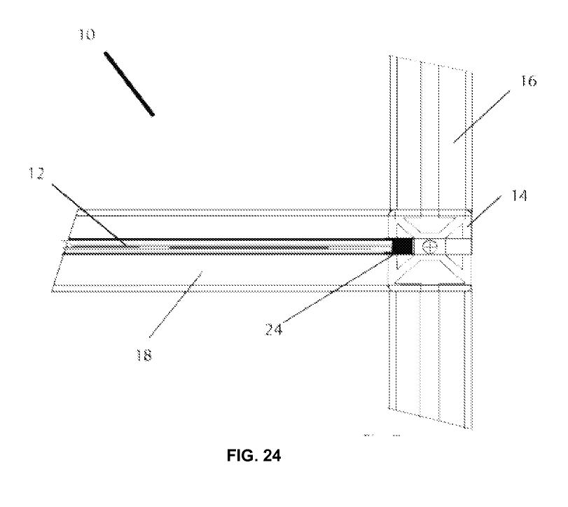

FIGS. 17 through 22 illustrate example embodiments of a solar photovoltaic apparatus 10 situated on reflective coating surface 20. The apparatus comprises vertical risers 14 joined with brace 18 and footings 16 and secured with plate 22. Bifacial solar module 12 is secured with panel clamp/gasket 24. The solar photovoltaic apparatus 10 holds the solar modules 12 in a sufficiently semi-vertical to vertical position and is sufficiently oriented on reflective coating surface 20 in such a way to maximize direct, indirect, reflective and diffused lighting on both the front and rear of solar modules 12.

The vertical risers 14 are sufficiently long enough to hold one solar module 12 on each side, in a portrait or landscape position, such as about, for example 40 to 90 inches in length. Brace 18 is sufficiently long enough to hold vertical risers 14 in a semi-vertical to vertical position, such as, for example, about 12 to 48 inches. The reflective coating surface 20 may be placed or applied under the solar photovoltaic apparatus 10 and extend sufficiently out in all directions such as about 12 to 36 inches from edge of solar photovoltaic apparatus 10.

The reflective coating surface 20 is a sufficiently sustainable surface which reflects and emits the suns light and heat, specifically ultraviolet, visible, and infrared light ways, with a sufficiently high SRI (Solar Reflective Index) such as about 75 or above.

Further, the other various components, including but not limited to, panel clamp/gasket 24 and all necessary fasteners to combine components of the solar photovoltaic apparatus 10 can be made of durable materials such that they are able to sustain and support the apparatus throughout the life of the apparatus.

The advantages of the present invention include, without limitation, more power production per square foot than a traditional solar system. The semi-vertical to vertical orientation allows substantial release of heat that is typically trapped under traditional solar arrays. An added advantage of the semi-vertical to vertical orientation is the harvesting of additional energy from reflective surfaces. The use of a surface coated with a highly reflective material that has an SRI of 75 or greater will generate substantially more power, as the vertical to semi-vertical orientation of the solar panels will permit the light to reflect off of these applied surfaces. Additionally, the reflective surface with an SRI of 75 or greater will be extremely efficient at reflecting the IR electrons that generate most of the heat found under traditional solar applications. The IR electrons are permitted to escape upward, cooling the surface and generating more energy in the solar cells. In addition, when the apparatus is used in conjunction with bifacial cell technology, back-to-back cell technology, or back-to-back panel technology, the amount of power produced per square foot increases exponentially. An increase of 30% to 100% more power is typical when the vertical or semi-vertical orientation is used. The apparatus also has the added benefit of being more economical to install per square foot than traditional solar because the pieces are designed to be constructed on the ground or in a warehouse then transported to the site largely preassembled. The preassembly increases quality control and minimizes the harmful effects to the roof or ground surface from repeated foot traffic during traditional installation.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention as claimed.

The word “example” or “exemplary” is used herein to mean “serving as an example, instance, or illustration.” Any embodiment described herein as an “example” or “exemplary” is not necessarily to be construed as preferred or advantageous over other embodiments.

1. A bifacial solar panel comprising:
a first panel comprising:
a transparent rigid front outer layer;
two or more front facing photo voltaic cells, arranged in strings, and encapsulated into a polymer to form a front facing panel of photo voltaic cells aligned in the same direction;
a second panel comprising:
a transparent rigid back outer layer;
two or more back facing photo voltaic cells, arranged in strings, and encapsulated into a polymer to form a back facing panel of photo voltaic cells aligned in the same direction;
wherein the front and back panels are arranged in a back to back configuration.

2. The bifacial solar panel of claim 1 wherein the transparent rigid front and back layers comprise glass, and the panels of photo voltaic cells comprise monocrystalline Si, polycrystalline Si, multicrystalline Si, amorphorus Si, nonocrystallne thin film Si, polycrystalline thin film Si, CIGS thin film, CdTe thin film, TiO2 thin film or a compounds of single or multi-junction cells.

3. The bifacial solar panel of claim 1 wherein the copolymer encapsulating the photo voltaic cells comprises Ethylene-vinyl acetate.

4. The bifacial solar panel of claim 1 wherein an insulating material is between the front facing panel of photo voltaic cells and the back facing panel of photo voltaic cells.

5. The bifacial solar panel of claim 4 wherein the insulating material is a rigid material providing support and structure to the bifacial solar panel.

6. The bifacial solar panel of claim 1 wherein the front and rear facing panels of photo voltaic cells each contain between 20 and 120 photo voltaic cells arranged in strings.

7. The bifacial solar panel of claim 1 further comprising a double junction box connected to the front and rear facing panels of photo voltaic cells.

8. The bifacial solar panel of claim 1 wherein the front facing panel of photovoltaic cells produce electrical energy primarily from direct exposure to sunlight and the rear facing panel of photo voltaic cells produce electricity primarily from reflective or indirect sunlight.

9. The bifacial solar panel of claim 1 wherein the panel is mounted on frame such that the front panel can be position at an angle of 0 degrees to 90 degrees from the horizontal plane.

10. The bifacial solar panel of claim 1 wherein the bifacial solar panel is part of an array of rooftop solar panels positioned on a reflective surface.

11. A method of producing electricity from two differently aligned solar panels, comprising:
coating a substrate with a reflective surface, the substrate being part of a rooftop;
providing a bifacial solar panel comprising:
a first panel comprising:
a transparent rigid front outer layer;
two or more front facing photo voltaic cells, arranged in strings, and encapsulated into a copolymer to form a front facing panel of photo voltaic cells aligned in the same direction;
a second panel comprising:
a transparent rigid back outer layer;
two or more back facing photo voltaic cells, arranged in strings, and encapsulated into a copolymer to form a back facing panel of photo voltaic cells aligned in the same direction;
producing electricity by exposing the first panel primarily to direct sunlight and exposing the second panel to primarily reflective or indirect sunlight.

12. The method of claim 11 further comprising:
providing a first bifacial solar panel aligned to capture direct sunlight on a first panel during a first part of the day; and
providing a second bifacial solar pane aligned to capture direct sunlight on a first panel during a second part of the day;
wherein the second panels of the first and second bifacial solar panels capture reflective or indirect sunlight reflected from the reflective coating on the substrate during both the first and second part of the day.

13. The method of claim 11 further comprising an array of bifacial solar panels.

14. The method of claim 11 wherein the reflective coating has a Solar Reflective Index of at least 75 and an emissivity index of at least 75;

15. The method of claim 11 further comprising:
maintaining the ambient temperature about the bifacial solar panel within 25 degrees Fahrenheit of optimal performance temperatures for the solar voltaic cells within the solar array, in part by preventing heating of the substrate due to the reflectivity and emissivity of the reflective coating.

16. A modular framing system for supporting a bifacial solar panel comprising:
one or more frame members, each comprising a channel and a gasket, wherein the framing member is configures to secure at least one edge of a bifacial solar panel;
two or more risers adjustably connected to the frame member with an adjustable attachment such that the frame member can be rotated to an angel with respect to the two or more risers;
a base portion connected to the riser;
wherein the modular framing system provides a minimal foot print on a mounting surface.

17. The framing system of claim 16 further comprising:
a first and second bifacial solar panel, each bifacial solar panel comprising:
a first panel comprising:
a transparent rigid front outer layer;
two or more front facing photo voltaic cells, arranged in strings, and encapsulated into a copolymer to form a front facing panel of photo voltaic cells aligned in the same direction;
a second panel comprising:
a transparent rigid back outer layer;
two or more back facing photo voltaic cells, arranged in strings, and encapsulated into a copolymer to form a back facing panel of photo voltaic cells aligned in the same direction;
wherein one or more framing members support one or more edges of each of the first and second bifacial solar panels and at least one central frame member supports an edge portion of the first bifacial solar panel and an edge portion of the second bifacial solar panel; and
wherein a riser is connected to the at least one central frame member.
